(19) United States
(12) Patent Application Publication
(10) Pub. No.: US 2020/0161509 A1
(43) Pub. Date: May 21, 2020

(54) QUANTUM-DOT LED BACKLIGHT MODULE FOR LED DISPLAYS

(71) Applicant: CORNING INCORPORATED, CORNING, NY (US)

(72) Inventors: Leonard Charles Dabich, II, Painted Post, NY (US); Stephan Lvovich Logunov, Corning, NY (US); Mark Alejandro Quesada, Horseheads, NY (US); William Allen Wood, Painted Post, NY (US)

(21) Appl. No.: 16/627,464

(22) PCT Filed: Jun. 29, 2018
(86) PCT No.: PCT/US2018/040208

§ 371 Date: Dec. 30, 2019

Related U.S. Application Data
(60) Provisional application No. 62/527,205, filed on Jun. 30, 2017.

(51) Int. Cl. H01L 33/50; H01L 33/06; H01L 33/54

(52) U.S. Cl. CPC H01L 33/504; H01L 33/06; H01L 2933/005; H01L 2933/0033; H01L 2933/0041; H01L 33/54

(57) ABSTRACT

The QD LED module (10) disclosed herein includes a support assembly (40), a circuit board (20), an LED (30) operably supported by the circuit board, wherein the LED emits blue light (36G). The QD LED module also has a QD structure (60) supported by the support assembly and axially spaced apart from the LED surface. The QD structure has an active area (AR) that includes a first region (R1) of QD material and a second region (R2) that has no QD material. A first portion of the blue light passes through the first region and is converted to red light (36R) and green light (36G). A second portion of the blue light passes through the second region. The QD material has a CIE color point that is shifted toward the yellow portion of the color space.

This application claims the benefit of priority under 35 U.S.C. § 119 of U.S. Provisional Application Ser. No. 62/527,205 filed on Jun. 30, 2017, the content of which is relied upon and incorporated herein by reference in its entirety.

### FIELD

The present disclosure relates to LED displays that use a quantum-dot backlight, and in particular relates to a quantum-dot LED backlight module for LED displays.

### BACKGROUND

Quantum-dot (QD) material is used in some types of LED displays to provide enhanced backlighting. The QD material has the advantage that it obviates the need for wavelength filters to generate the R-G-B wavelengths of light needed to form a color display.

A downside of QD-based backlighting is that the QD material sensitive to temperature and light flux from the LED light source. These sensitivities require that the LED light source be separated from the QD material. But this separation runs counter to the need for the QD LED packages or “modules” that form the QD-based backlight to be compact and have a small footprint while also having high brightness.

### SUMMARY

An aspect of the disclosure relates to a QD LED display that uses an LED that emits blue light and a QD material having a color point on the color gamut (e.g., CIE 1931) that is shifted from the conventional QD color point (e.g., (0.28, 0.2) to the yellow or yellow-green portion of the color space (e.g., x>0.35, y>3.75). A first portion of the blue light from the LED does not pass through the color-shifted QD material. A second portion of the blue light is directed to the QD material and is used (i.e., converted by the QD material) to form green and red light. This configuration allows for the flux of blue light on the QD material to be reduced (e.g., by at least 10% and as much as 50%), which in turn increases the longevity and reduces the time to failure of the QD material, while also improving the overall backlighting brightness as compared to backlights that use conventional QD LED modules.

Other aspects of the disclosure include: 1) the use of at least one spacer layer and a support assembly that supports heat conduction away from the QD material and back to the circuit board that supports the LED, wherein the circuit board acts as a heat sink; 2) a scattering layer configured to substantially uniformize the blue light to avoid hot spots when irradiating the QD material; 3) a hermetic seal formed by a transparent cap that serves as a barrier to oxygen and moisture, which can reduce the performance of the QD material over time. The QD material can also be part of a hermetically sealed QD chiplet, obviating the need for the transparent cap.

An embodiment of the disclosure is directed to a QD LED module that includes: a circuit board; an LED operably supported by the circuit board, the LED having a surface that emits blue light; and a QD structure supported within the interior of the support assembly and axially spaced apart from the LED surface by a distance D1, the QD structure having an active area that includes at least one first region of QD material and at least one second region that has no QD material, wherein a first portion of the blue light from the LED passes through the at least one first region and is converted by the QD material to red and green light, and wherein a second portion of the blue light passes through the at least one second region.

Another embodiment of the disclosure is directed to a QD LED module that includes: a support assembly having an interior; a circuit board; an LED operably supported by the circuit board, the LED having a surface that emits blue light; a QD structure supported within the interior of the support assembly and axially spaced apart from the LED surface by a distance D1, the QD structure having an active area that includes at least one first region of QD material and at least one second region that has no QD material, wherein a first portion of the blue light from the LED passes through the at least one first region and is converted to red and green light, and wherein a second portion of the blue light passes through the at least one second region; and at least one spacer layer disposed between the LED and the QD structure so that there is no air space between the LED and the QD structure.

Another embodiment of the disclosure is directed to a QD LED module that includes: a support assembly having at first end, a second end at least one sidewall and an interior; a circuit board disposed at or adjacent the second end of the support assembly, wherein the circuit is in thermal contact with the at least one sidewall of the support assembly; an LED operably supported by the circuit board, the LED having a surface that emits blue light; a QD structure supported within the interior of the support assembly and axially spaced apart from the LED top surface by a distance D the QD structure having an active area that includes at least one first region that comprises QD material configured to receive and convert the blue light to red light and green light and at least one second region that does not include any QD material, wherein the QD material of the at least one first region has an (x,y) CIE color point of x>0.35 and y>0.375; and at least one spacer layer disposed between the LED and the QD structure and that is in thermal contact with the at least one sidewall so that there is no air space between the LED and the QD structure.

Another embodiment of the disclosure is directed to a method of forming white light using a QD material supported on a QD structure. The method includes: generating blue light from an LED; passing a first portion of the blue light through the QD material of the QD structure to form green and red light; passing a second portion of the blue light through the QD structure but not through any of the QD material; and combining the green and red light and the second portion of the blue light to form the white light.

Additional features and advantages are set forth in the Detailed Description that follows, and in part will be apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1 is a schematic diagram of a generalized or “basic” QD LED module that can be used in a backlight apparatus for a QD LED display;

FIGS. 2A through 2D are schematic side views of a first example of a QD LED module according to the disclosure;

FIGS. 3A and 3B are schematic side views of a second example QD LED module according to the disclosure;

FIGS. 4A through 4D are top-down views of example QD structures and example patterns of QD material supported by the QD structures that allow a portion of the blue light to be transmitted through the QD structure without having to pass through the QD material;

FIG. 5A through FIG. 5C are schematic side views of a third example QD LED module according to the disclosure;

FIGS. 5D and 5E are close-up side views of the LED and the QD structure showing how a scattering layer can be disposed between the LED and the QD structure, and also showing the two main dimensional parameters D1 and DG of the QD LED module;

FIG. 6 is a plot of the (x,y) coordinates of the CIE 1931 color space (“CIE coordinates”) as a function of the QD material thickness DQ (mm) illustrating how the CIE coordinates can change by changing the thickness DQ of the QD material;

FIG. 7 is a contour plot of predicted average brightness B (nits) as a function of the module dimensions D1 (mm) and DG (mm) for the QD LED module of FIG. 4A for a first example QD material;

FIGS. 8A and 8B are contour plots of the average x CIE coordinate and y CIE coordinate, respectively, as a function of the module dimensions D1 (mm) and DG (mm) for the first example QD material;

FIG. 9 is a plot similar to FIG. 7 and shows the predicted brightness B (nits) for a second example QD material as a function of the module dimensions D1 (mm) and DG (mm); and

FIGS. 10A and 10B are plots similar to FIGS. 8A and 8B, but for the second example QD material.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

Cartesian coordinates are shown in some of the Figures for the sake of reference and are not intended to be limiting as to direction or orientation.

The terms “downstream” and “upstream” refer to the relative locations of a component, element, etc., based on the direction of travel of light, so that A being downstream of B means that light is first incident on B and then on A. Likewise, A being upstream of B means that light is first incident on A and then on B.

### Design Considerations

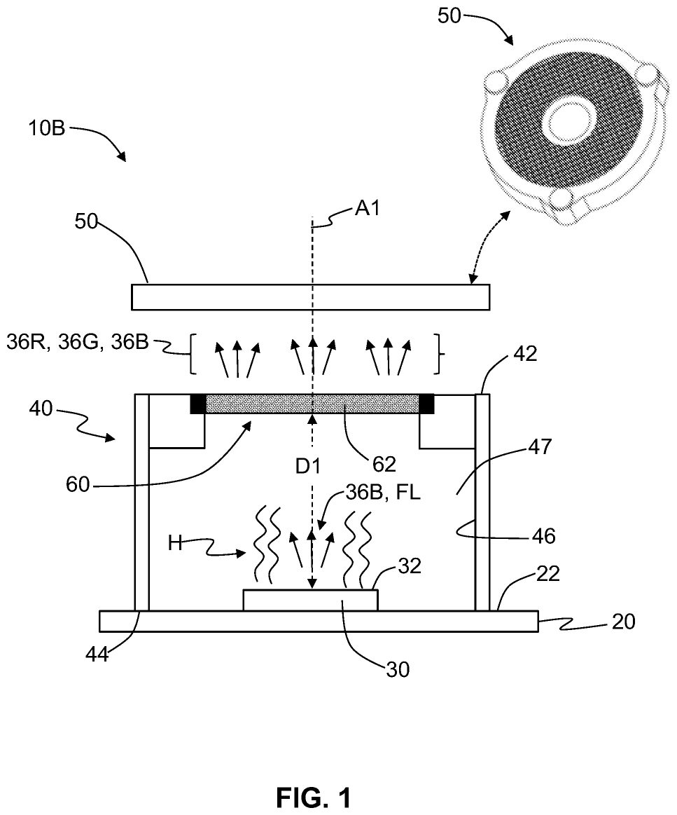

FIG. 1 is a schematic side view of a generalized or “basic” QD LED package or “module” 10B that can be used to form a backlight apparatus for a QD LED display. The basic QD LED module 10B is based on phosphor-based LED modules and includes a circuit board 20, such as a printed circuit board (PCB), that operably supports an LED 30. The LED 30 has a top surface 32 from which is emitted blue light 36B. The basic QD LED module 10B also includes a support assembly 40 having a top end 42, a bottom end 44, and at least one sidewall 46 that defines an interior 47. The basic QD LED module 10B can include a lens element 50 disposed adjacent the top end 42 of the support assembly 40. The close-up inset shows an example of the lens element 50.

The support assembly 40 operably supports within its interior 47 a QD structure 60 that includes a QD material 62. The QD structure 60 is sometimes referred to as a “QD chiplet.” In an example, the QD structure 60 comprises a polymer matrix and the QD material 62 is supported by (e.g., in or on) the polymer matrix. In an example, the QD structure can comprise a hermetic QD chiplet, which obviates the need to hermetically seal the QD LED module using a cap, as discussed below.

The distance from the top surface 32 of the LED 30 to the QD material 62 is measured along a vertical axis A1 and is denoted D1, and as discussed below is one of the main module dimensions. The QD material 62 is configured so that a portion of the blue light 36B is converted to red light 36R and green light 36G while a portion of the blue light is transmitted therethrough (i.e., is unconverted), thereby providing red, blue and green colors for use in the (color) QD LED display. The lens 50 can be used to redirect the red light 36R, green light 36G and blue light 36B to uniformize the light distribution for backlighting purposes.

The blue light 36B emitted by the LED 30 has an associated optical flux FL, which can be measured in units of Watts per meter squared (W/m²). The LED 30 also generates heat H that reaches the QD structure 60 and that causes the QD material 62 to have a temperature TF. QD LED displays require that the optical flux FL and the temperature TF experienced by the QD material 62 be well managed for long-life operation. This requires that the distance D1 be sufficient to reduce peak-shifting and peak-broadening emission degradation as well as yield reduction from prolonged high-temperature and high-flux operation.

Without being bound by theory, it is generally believed that degradation of QD material is due principally to QD-ligand and polymer matrix breakdown as well as defects formed in the surface of QDs. The type of LED 30 used in a QD LED module for backlighting apparatus typically produces an optical flux FL of about 100 W/cm², which is too high for most QD materials. At the same time, cost requirements are such that QD-LED modules need to have a small footprint and be simple while also being easy to integrate with other modules. This is in addition to the QD LED module being hermetically sealed and enduring high-flux and high-temperature operation over a 10-year period.

A key requirement for a QD LED display is that it operate over 30,000+ hours with less than a 10% change in the color gamut. This requirement limits the amount of flux FL of blue light 36B incident upon the QD material 62 to be less than about 2.5 to 3 W/cm². The typical 55″ TV with 1000 nits brightness requires about 435 W of blue light, assuming a luminous efficiency (LE) of 120 W/lm, or 290 W at 180 W/lm, from about 100 cm² of the combined area of the QD material 62, regardless of how many individual LEDs 30 are used. It is noted here that the LE of a TV panel describes the ability of a panel to transform the incident light power (W) into light humans can perceive (lumens or lm), and plays a large role in the calculation for the total LED power required to construct a 1000 nit TV. The 290-520 W of power of blue light 36B used in the 55″ TV's LED-count calculation assumes a panel LE of at least 100 lumens/W. Some panels have LE values as high as 180 lumens/W.

Depending on the design of the LED 30, the minimum area of QD material 62 required is determined by the above considerations as well as by the limits of optical technology in distributing light from a finite number of LEDs. To determine the minimum area of the QD material 62 needed, the emission of blue light 36B needs to be close enough to the QD material to uniformly illuminate it but not be so close as to exceed the flux limit of FL<2.5 W/cm to 3 W/cm².

It is also noted that increasing the brightness of QD LED displays means subjecting the QD material 62 to increasing amounts of heat H. Thus, another design consideration is how to dissipate the heat H generate by the LED 30 and that can reach the QD material 62 so that the temperature TF of the QD material 62 stays below a threshold temperature TTH, which in an example is 90° C. If the temperature TF of the QD material 62 exceeds the threshold temperature TTH, then the QD LED backlighting performance can degrade due to at least one of: a) a shifting emission peak (˜1 nm per 10° C.); b) peak width broadening (prefer to keep narrow, e.g., <24 nm); and c) accelerated aging of the QD material and polymer matrix breakdown.

Thus, some main design goals of the QD LED modules disclosed herein include one or more of: 1) the flux of the blue light 36 incident upon the QD material be substantially uniform and up to or close to the maximum allowable flux; 2) maximizing the LED brightness; and 3) stable output of red and green light from the QD material over a relatively long time duration, e.g., 10 years.

### First QD LED Module Example

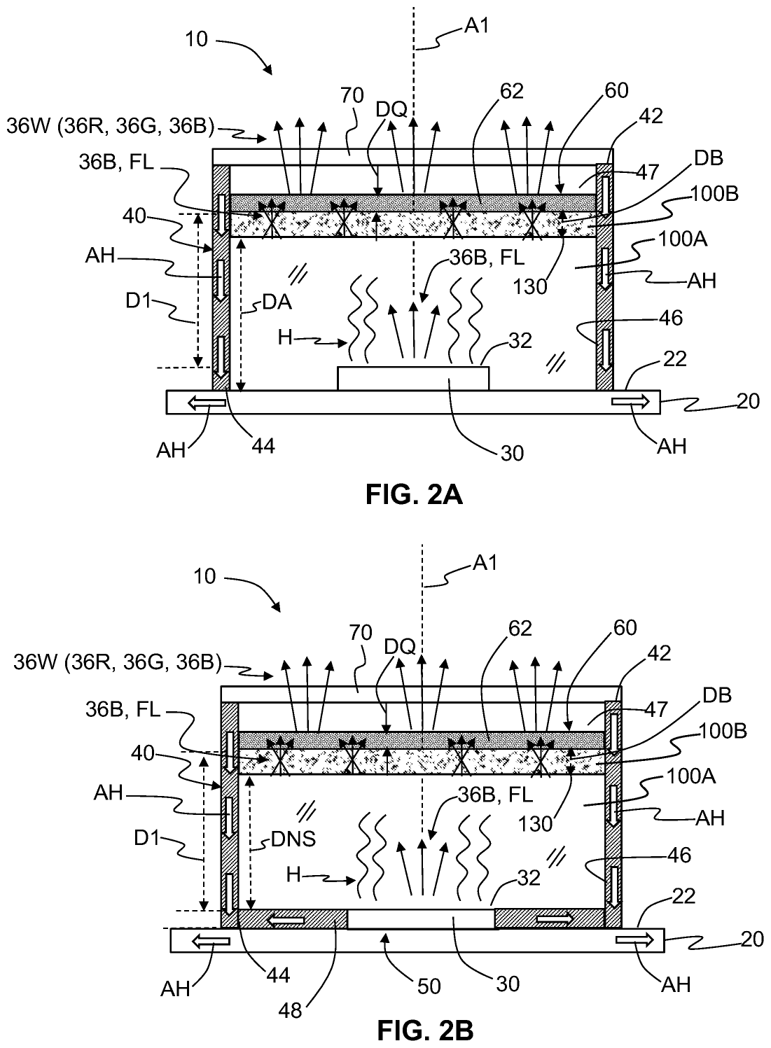

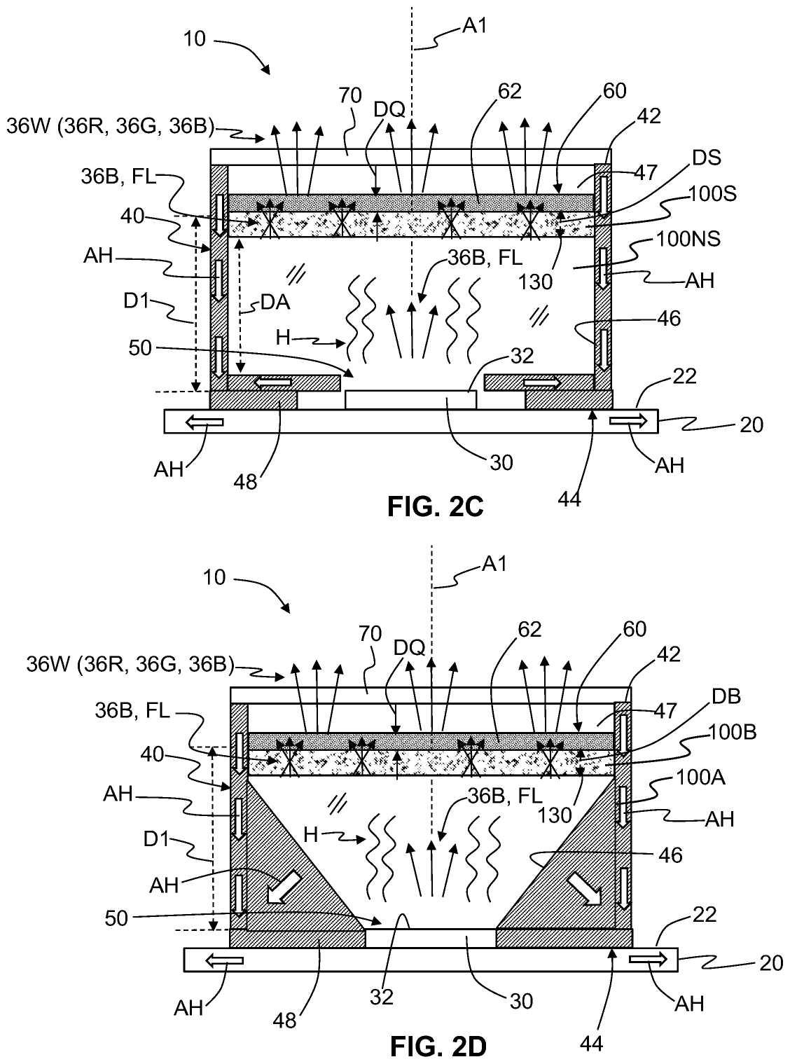

FIG. 2A is a schematic side view of a first example of a QD LED module 10 as disclosed herein. The QD LED module 10 includes the same basic elements of the basic QD LED module 10B of FIG. 1 as well as additional performance-enhancing components and features that address the design considerations described above. Some embodiments of the QD LED module 10 can employ the lens element 50, which is omitted for ease of illustration.

The QD LED module 10 of FIG. 2A includes in the interior 47 a first spacer layer 100A that resides downstream of the LED 30 and in an example resides immediately atop the LED top surface 32 and optionally also atop at least a portion of the top surface 22 of the PCB 20. The first spacer layer 100A is transparent and non-scattering and has an axial thickness DA. In an example, the first spacer layer 100A comprises or consists of silicone.

A second spacer layer 100B resides immediately atop (i.e., downstream of) the first spacer layer 100A. The second spacer layer 100B is a scattering layer and has a thickness DB. In an example, the second spacer layer 100B is configured to scatter blue light 36B from the LED 30. In an example, the second spacer layer 100B comprises silicone along with scattering particles 130 (e.g., TiO₂) embedded therein.

Thus, in an example, the first and second spacer layers 100A and 100B occupy the portion of the interior 47 of the support assembly 40 between the LED 30 and the QD structure 60 so that there is no air space between the LED 30 and the QD material 62. This configuration is used to promote the transfer of heat H away from the QD material by conducting the heat to the support assembly 40. In an example, at least one spacer layer 100A is employed, wherein the spacer layer has a thermal conduction greater than that of air. In an example, a single spacer layer 100 that includes scattering features sized to scatter the blue light 36B from the LED 30 can be employed, as described below. In an example, the QD material 62 has a thickness DQ.

In an example, the QD LED module 10 can include a cap 70 that resides on the top side 42 of the support assembly 40 and along with the support assembly serves to hermetically seal the interior 47 of the support assembly and the components therein, and in particular the QD structure 60. The cap 70 can also be attached directly to the QD structure 60 since only the QD material 62 needs to be hermetically sealed. In an example, the cap 70 can be in the form of the aforementioned lens element 50, which can be used to redirect the white light 36W to provide more uniform illumination from the QD LED module 10. Such lens elements 50 are sometimes referred to in the art as secondary lens elements. The QD structure 60 can also comprise a hermetically sealed QD chiplet, thereby obviating the need for the cap 70.

Thus, in an example, the non-scattering first spacer layer 100A serves as a first thermal conducting layer that conducts the heat H over to the sidewalls 42 of the support assembly 40. The sidewalls 46 of the support assembly 40 can be made of a material with a relatively high thermal conductivity, such as a metal, so that the heat H generated by the LED can be conducted back to the PCB 20 and then dissipated, as indicated by the arrows AH. In this case, the PCB 20 acts as a heat sink.

Example materials with a relatively high thermal conductivity (e.g., greater than 20% that of pure copper) include metals such as, aluminum, copper, stainless steel and other metal alloys, etc. In an example, the thermally conductive material or materials that make up the sidewalls 46 has or have a thermal conductivity of greater than 50 Wm⁻¹K⁻¹.

The second spacer layer 100B serves as a second thermal conducting layer that also conducts heat H to the sidewalls 46 of the support assembly 40. The second spacer layer 100B also acts to scatter and uniformize the blue light 36B to avoid “hot spots” forming at the QD material 62. In other words, the spatial intensity uniformity of the blue light 36B incident upon the QD structure 60 is improved by the second spacer layer 100B due its light-scattering properties.

The second spacer layer 100B also facilitates the substantially uniform generation of red and green light 36R and 36G by the QD material 62 while also facilitating the substantially uniform transmission of a portion of the blue light 36B through one or more regions of the QD structure that have no QD material, as described below.

In an example, the LED has dimension of 2 mm×2 mm while the thickness DA is between 1 mm and 8 mm and the thickness DB is between 0.05 and 0.5 mm.

FIG. 2B is similar to FIG. 2A and illustrates an example of the QD LED module 10 wherein the support assembly 40 includes a bottom wall 48 with an aperture 50. The LED 30 can reside within the aperture 50 as shown or adjacent the aperture 50, as shown in FIG. 2C. In either configuration, the bottom wall 48 can be made of a thermally conducting material (e.g., the same material as the sidewalls 46) to provide for the additional conduction of heat H away from the LED 30. In an example, the bottom wall 48 serves as a heat sink and in an example is made of a high thermal conductivity metal such as copper.

FIG. 2D is similar to FIG. 2C and shows an example embodiment where the support assembly 40 is configured with sloped sidewalls 46. In the example configuration of FIG. 2D, the lower portion of support assembly 40 is made thick so that it can act as a heat sink and conduct heat away from the QD material and the first spacer layer 100A. (e.g., to the PCB 20).

### Second QD LED Module Example

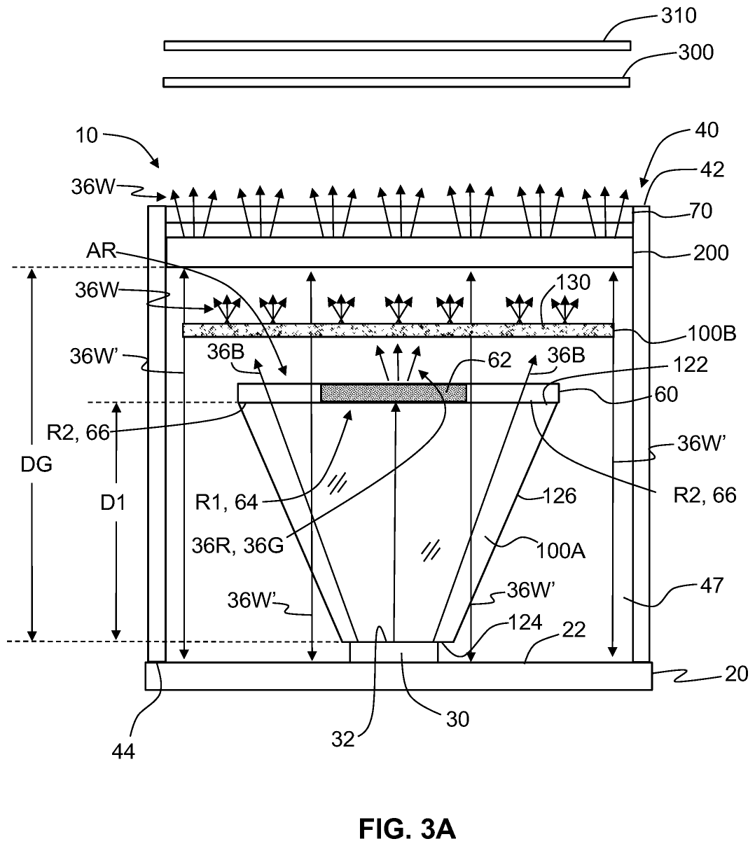

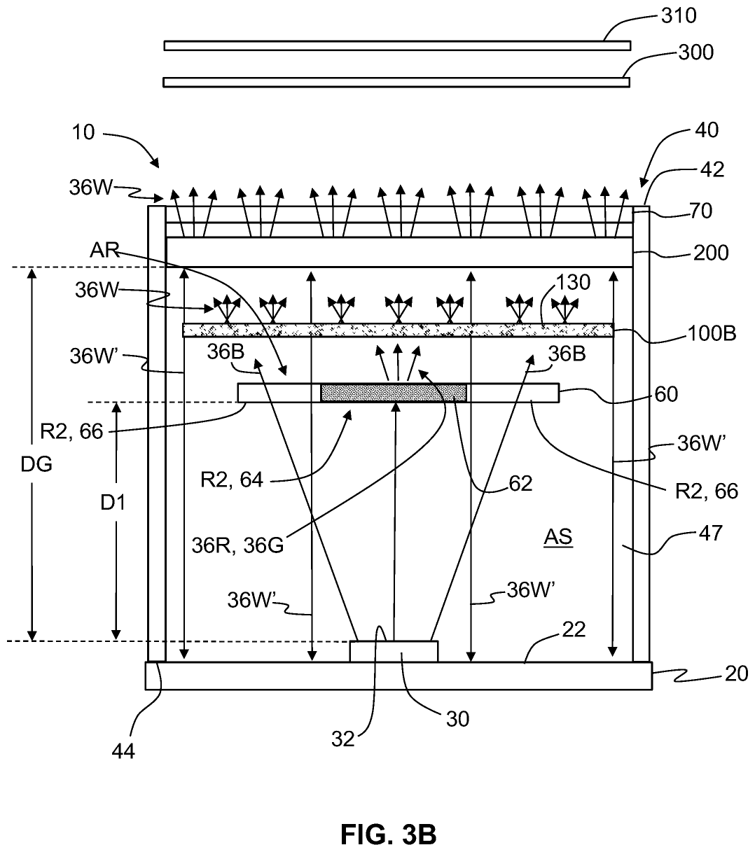

FIGS. 3A and 3B are schematic side views of a second example QD LED 10. The QD structure 60 has an active area AR through which blue light 36B from the LED passes, as described below. The active area AR of the QD structure 60 includes at least one first region R1 (e.g., a central region 64) of QD material 62 and at least one second region R2 (e.g., an outer region 66) where there is no QD material.

The QD LED 10 of FIG. 3A also includes the aforementioned non-scattering first spacer layer 100A atop the LED 30 and the scattering second spacer layer 100B between the LED 30 and the QD structure 60 so that there is no air space between the LED and the QD structure. The QD LED 10 of FIG. 3B is the same as that of FIG. 3A except that it does not employ the non-scattering first spacer layer 100A, which leaves an air space AS between the LED 30 and the QD structure 60.

With reference to FIG. 3A, the non-scattering firsts spacer layer 100A has a top side 122, a bottom side 124 and can have at least one angled sidewall 126. The bottom side 124 can reside directly atop the top side 32 of the LED 30. The QD structure 60 is disposed proximate to or directly atop the top side 122 of the non-scattering first spacer layer 100A. The scattering second layer 100B resides downstream of the QD structure 60, either proximate to or directly atop and in contact with the QD structure 60.

The examples of the QD LED 10 of FIG. 3A and FIG. 3B each includes a light-homogenizing medium 200, which resides downstream of the scattering second layer 100B and either proximate to or immediately atop of the scattering second layer. The light-homogenizing medium 200 has a structure that receives light, and by one or more of reflection, refraction, diffraction, scattering and transmission, acts to substantially mix or homogenize light that passes therethrough. In an example, the light-homogenizing medium 200 is in the form of a sheet. Examples of suitable light-homogenizing medium 200 are described in U.S. Pat. Nos. 7,540,630, 7,325,962 and US20080266875A1, well as in Chinese Patents No. CN 103383084 and CN201210135443A, all of which are incorporated herein by reference. In an example, the light-homogenizing layer 200 can be configured to redirect the light so that it has a greater angular spread up exiting the light-homogenizing layer than the angular spread of light incident upon the light-homogenizing medium.

The light-homogenizing medium 200 resides at an axial distance DG from the top surface 32 of the LED 30. The distance DG constitutes a second main dimensional parameter of the QD LED module 10 (the first being the dimension D1 introduced and discussed above).

The example QD LED 10 of FIGS. 3A and 3B each optionally includes the cap 70 attached to the top side 42 of the support assembly 40 and that hermetically seals the components residing in interior 47 and in particular hermetically seals the QD material 62. In an example, the cap 70 can be made of glass, and in a particular example is made of a chemically strengthened glass. As mentioned above, the cap 70 can be in the form of the lens element 50 as shown in FIG. 1. The cap 70 can be omitted in the case where the QD material 62 is already hermetically sealed as part of the QD structure 60 (e.g., when the QD structure comprises a hermetically sealed QD chiplet).

In the example of the QD LED 10 of FIG. 3A, the blue light 36B emitted from the LED 30 travels through the non-scattering spacer layer 100A and then to the QD structure 60. In the example of FIG. 3B, the blue light 36B travels through free space (i.e., an air space AS) to the QD structure 60. In either case, a portion of this blue light 36B is incident upon the QD material 62 in the central region 64 (i.e., first region R1) of the QD structure and is converted by the QD material into red and green light 36R and 36G. Meantime, another portion of the blue light 36B travels through the outer region 66 (i.e., second region R2) of the QD structure 60 where there is no QD material 62 and so remains blue light. Because the blue light 36G is already being provided by transmission of the blue light through the second region that has no QD material 62, the formulation (configuration) of the QD material 62 can be one that has a higher concentration of red QDs and green QDs than the standard QD material, which is required to transmit a substantial portion of the blue light incident thereon.

The transmitted blue light 36B through region R1 and the newly generated red light 36R and green light 36G from region R2 are incident upon the scattering layer 160, which scatters the blue light 36B, the green light 36G and the red light 36R to make “initial” white light 36W′, i.e., white light that does not have a high degree of uniformity. The initial white light 36W′ is then incident upon the light-homogenizing medium 200, which acts to homogenize (i.e., mix, blend, etc.) the blue, red and green components of the initial white light 36W′ to form substantially uniformized white light 36W that ultimately exits the QD LED module 10 and that is used as backlight for a display (not shown).

In an example, the light-homogenizing medium 200 is configured to reflect some of the initial white light 36W′ back down to the PCB 20, whose top surface 22 is reflective so that initial white light 36W′ is reflected back through the scattering layer 160 and the light-homogenizing medium 200, thereby providing for greater uniformization of the white light 36W that is finally ultimately emitted by the QD LED 10. In an example, the reflectivity of the light-homogenizing medium 200 is in the range from 90% to 99% and the reflectivity of the top surface 22 of the PCB 20 is in the range from 85% to 99%. In an example, the support assembly 40 is configured such that the interior 47 allows for such reflection between the PCB 20 and the light-homogenizing layer 200. For example, the sidewalls 46 of the support assembly 40 can be made vertical rather than angled (see, e.g., FIG. 2D).

Thus, the QD LED modules 10 of FIGS. 3A and 3B are configured to intentionally transmit some of the blue light 36B from the LED 30 through the QD structure 60 without being incident upon any QD material 62 supported thereby as part of the process of generating the white light 36W. Moreover, by making more efficient use of the blue light 36B that is incident upon the QD material 62 in the central region 64 (i.e., second region R2) by converting the blue light incident thereon only to red light 36G and red light 36R, the peak irradiance (flux FL) incident upon the QD material 62 can be reduced. In an example, the QD material 62 can use higher concentrations of red QDs and green QDs, with sizes chosen for deeper green and red colors necessary for a greater color shift relative to the standard QD material (e.g., with a CIE color point of (0.28, 0.20). Computer-based modeling of the QD LED module 10 shows that appreciable brightness improvements may be obtained from the QD LED module.

FIGS. 3A and 3B also show an example that includes a diffuser 300 and one or more brightness-enhancing films (BEFs) 310 that reside downstream of the cap 70 and that can reside either proximate to or in contact with the cap 70. The BEFs 310 can be used to enhance the brightness of the QD LED module 10 by using refraction and total internal reflection (TIR) to selectively direct the white light 36W exiting the QD LED. In an example, crossed BEFs 310 are used. The diffuser 300 is used to diffuse the white light 36W to make the white light 36W even more uniform before it reaches the downstream portions of the QD LED display (not shown).

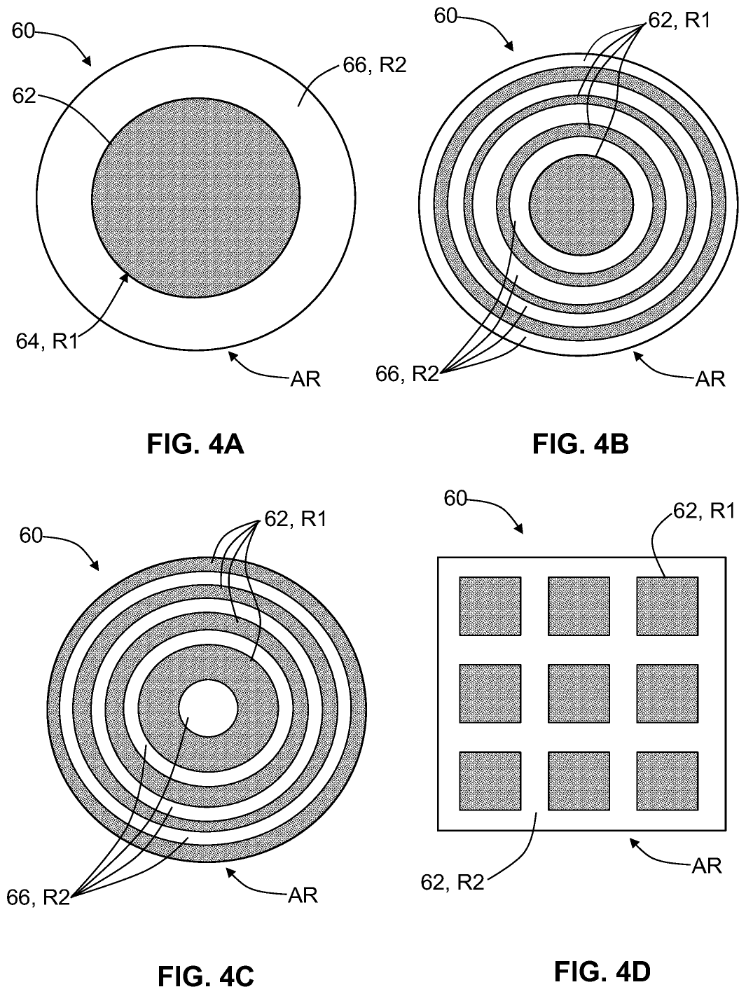

FIGS. 4A through 4D are top-down views of example QD structures 60 and example patterns or first regions R1 of QD material 62 supported by the QD structures along with second regions R2 having no QD material and that allow a portion of the blue light 36B to be transmitted through the QD structure without having to pass through the QD material. In an example, the active area AR includes at least one first region R1 and at least one second region R2.

FIG. 4A shows the basic configuration of the QD structure 60 of FIGS. 3A and 3B wherein the QD material 62 is concentrated in a single first region R1 (i.e., a central region 64) of the support assembly and wherein there is no QD material in a single second region R2 (i.e., the outer region 66). FIG. 4B shows another example configuration having multiple first regions R1 of QD material 62 defined by a central disk-like region and multiple concentric regions, along with multiple concentric second regions R2 that have no QD material 62. FIG. 4C is similar to FIG. 4B and shows an example with a different annular configuration for first regions R1 of QD material 62 and the second regions R2 of no QD material. FIG. 4D shows another example configuration of the QD material 62 as arranged in a number of first regions R1 in the form of a regular pattern of small squares on a larger square QD structure 60. The space between the first regions of QD material 62 defines the second region R2 of no QD material.

Other distributions or configurations of the QD material 62 that define one or more first regions R1 and one or more second regions R2 are contemplated herein beyond just the few examples shown in FIGS. 4A through 4D. For example, random islands of QD material 62 can be used, as well as islands having different QD concentrations, etc. The ratio of the QD material area to the non-QD material area defines the relative amounts of transmission of blue light 36B and generation of red and green light 36R and 36G.

In an example, the amount of non-QD material area of the one or more regions R2 is in the range of 10% to 30% of the total active area AR of the QD structure 60.

### Third QD LED Module Example

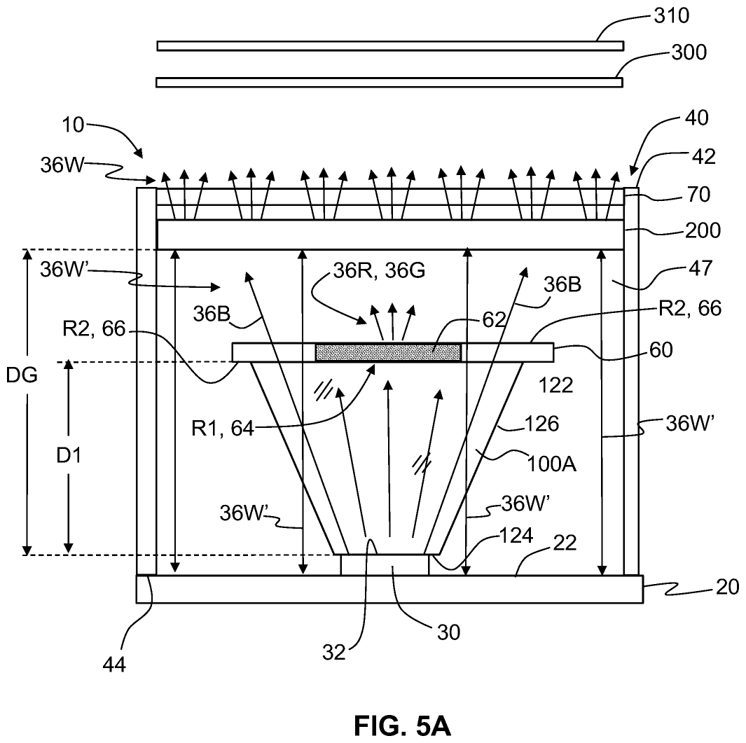

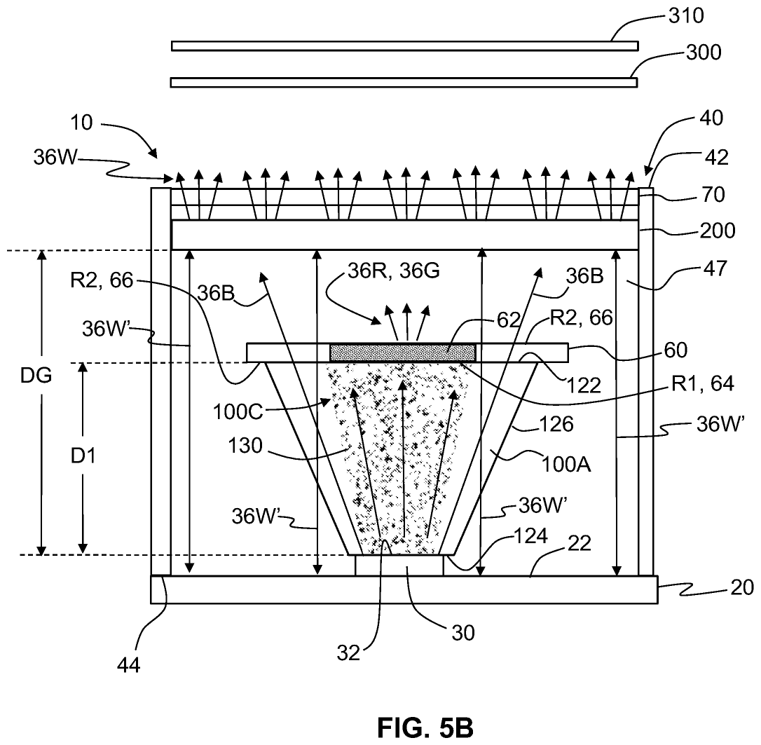

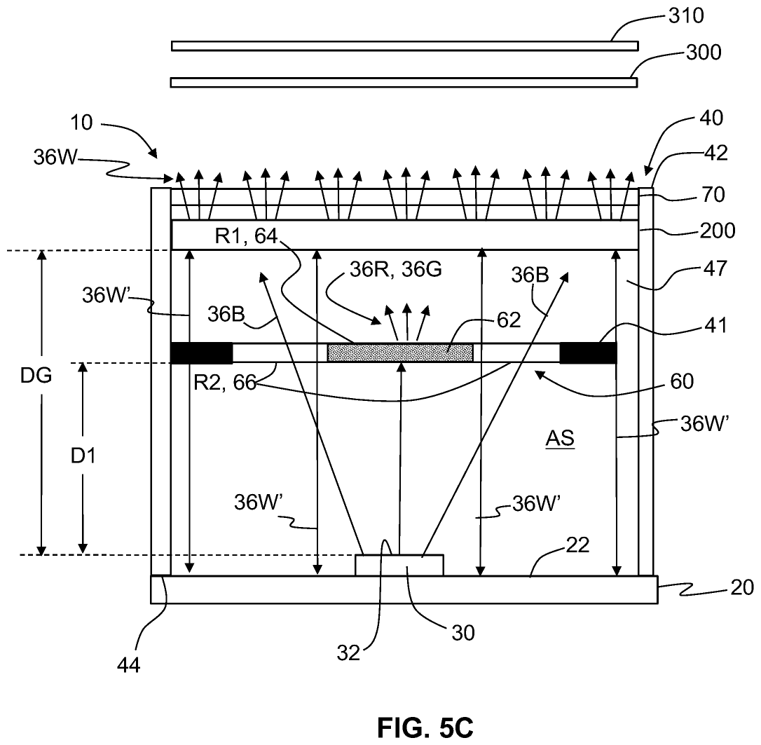

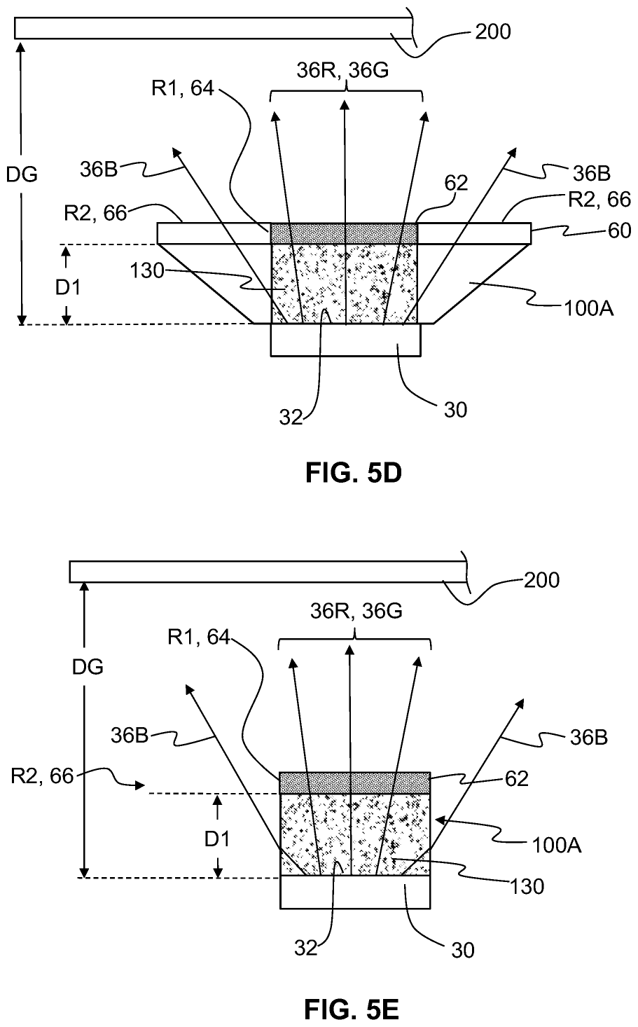

FIG. 5A shows a third example of the QD LED module 10 similar to FIG. 3A but where scattering layer 100B is removed so that there is only a single spacer layer 100A. In this example, the light-homogenizing medium 200 is used to combine the blue light 36B, the green light 36G and the red light 36R that make up the initial white light 36W′ to form white light 36W. Note that the less uniformized white light 36W′ is still reflected by the light-homogenizing medium 200 back toward the reflective surface 22 of the PCB 20, which reflects the white light 36W′ back through the light-homogenizing medium 200 to improve the uniformity of the white light 36W that exits the QD LED 10.

FIG. 5B is similar to FIG. 5A and shows a related example where the spacer layer 100A includes a central portion 100C that includes scattering particles 130. The scattering particles 130 are arranged so the blue light 36B incident upon the QD material 62 in the central portion 64 (i.e., first region R1) of the QD structure 60 is scattered and uniformized while the blue light that travels through the outer region 66 (i.e., second region R2) of the QD structure is not scattered. The scattering particles 130 are configured to lengthen the light path for blue light 36B within the QD material 62 to induce QD-photon interactions and thus generate more green light 36G and red light 36R. In an example, the scattering particles 130 comprise titania. In an example, the scattering particles 130 are supported in silicone, which assists in conducting heat H away from the QD structure 60. This allows the QD structure 60 to be placed closer to the LED, e.g., with distance D1 in the range from 1 mm to 5 mm.

FIG. 5C is similar to FIGS. 5A and 5B and show an example where there is no spacer layer between the LED 30 and the QD structure 60 so that the blue light 36B travels through free space (i.e., an air space AS) from the LED to the QD structure. In the example of FIG. 5C, the QD structure 60 is shown mounted to the support assembly 40 by thermally conducting support members 41

FIGS. 5D and 5E are close-up side views that show two variations of the third example embodiment of the QD LED module 10 wherein the scattering particles 130 are located in close proximity to or are a part of the QD structure.

### Adjusting the CIE Coordinates of the QD Material

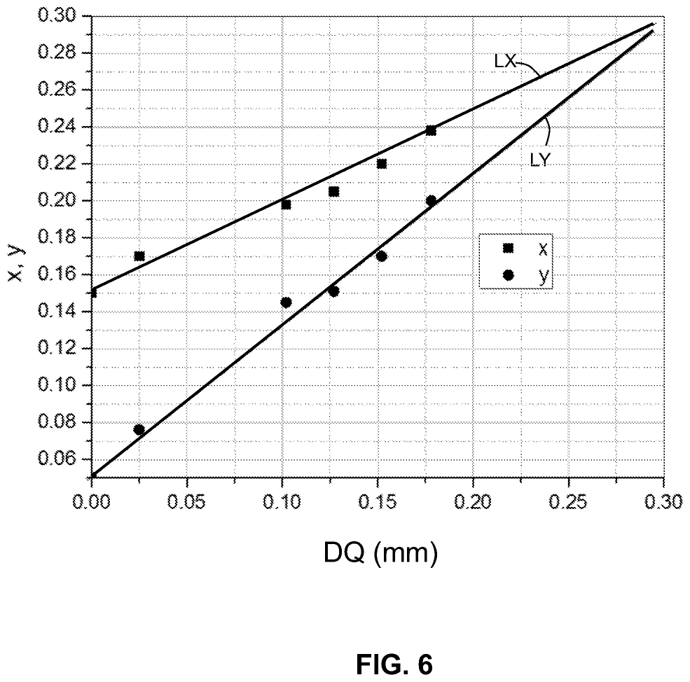

FIG. 6 is a plot of the (x,y) coordinates of the CIE 1931 color space (“CIE coordinates”) as a function of the QD material thickness DQ (mm) The plot of FIG. 6 illustrates how the (x,y) CIE coordinates can change by changing the thickness DQ of the QD material. In FIG. 6, the x CIE coordinates lie along the line LX while the y CIE coordinates lie along the line LY. The same effect in changing the (x,y) CIE coordinates can be obtained by changing the concentration c of the red QDs and the green QDs. In an example, this is accomplished by keeping product c·DQ constant.

For a particular QD material 62 with an initial concentration of red and green QDs, one can either double the concentration c of red and green QDs or double the thickness DQ to move the y CIE coordinate by 0.09 and the x CIE coordinate by 0.05. For example, for a CIE color point shift from (0.23, 2) to (0.47, 55) (which is the highest blue point in the CIE color space), one needs to increase the concentration c of red and green QDs by about 3.5× to 5×. For reference, the CIE color point (0.28, 0.24) is the target color point for FOS (“front of screen”) for white light in LED displays, with no picture and maximum white light throughput.

### Improved Brightness

The QD LED module 10 can provide improved brightness as compared to conventional modules that used standard QD material. This is made possible because the QD LED module 10 disclosed herein can use a QD material 62 having a shifted CIE color point relative to that of a standard QD material used in conventional QD LED modules. For reference, a standard QD material 62 was obtained and its CIE color point measured to be (0.28, 0.20).

### Example 1

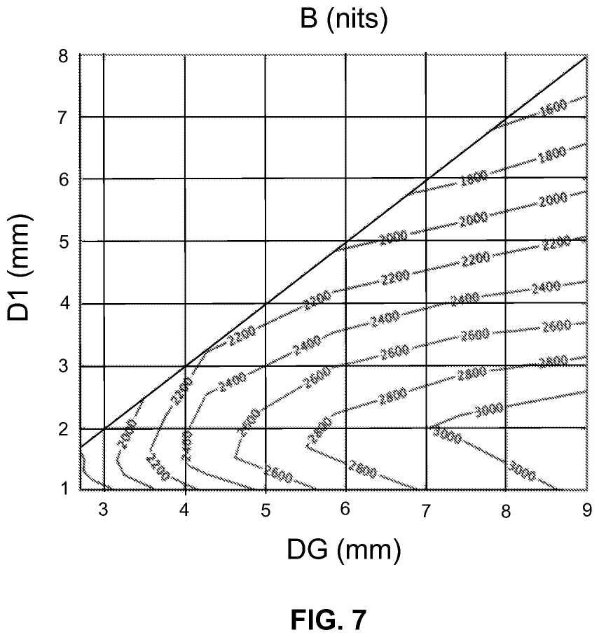

FIG. 7 is a contour plot of the predicted average brightness B (nits) as a function of the module dimensions D1 (mm) and DG (mm) based on the QD LED 10 of FIG. 4A and for a first example QD material 62 having a CIE color point (x,y)=(0.47, 0.47), which is in the yellow portion of the CIE 1931 color space. The color point shift (Δx, Δy) relative to the measured CIE color point (0.28, 0.20) is Δx=0.19 and Δy=0.27.

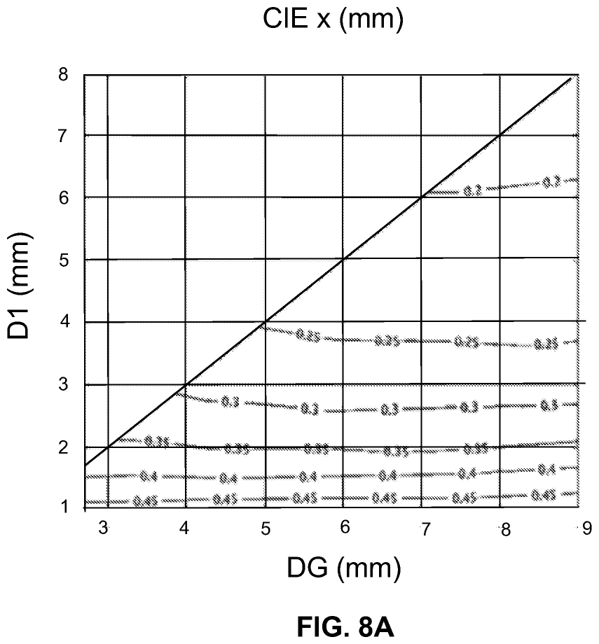

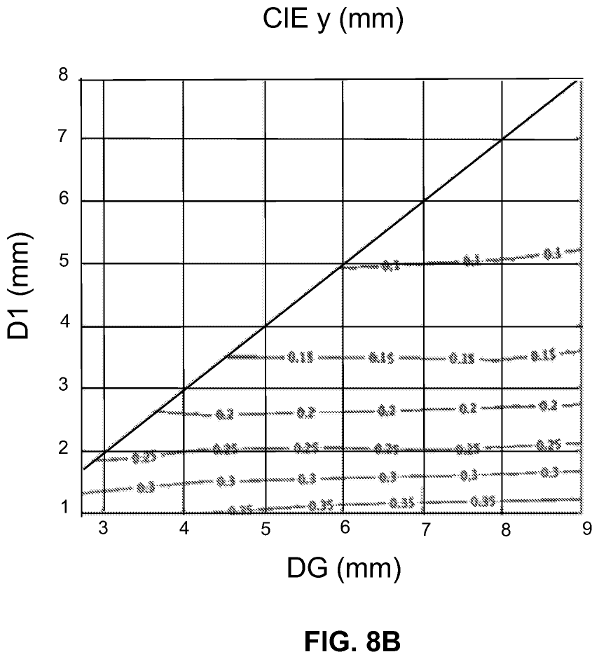

FIGS. 8A and 8B are contour plots of the average x CIE coordinate and y CIE coordinate, respectively, for the CIE 1931 color space as a function of the module dimensions D1 (mm) and DG (mm) for the first example QD material 62. The plots of FIGS. 8A and 8B show that the (x,y) CIE color coordinates only weakly depend on the position or distance DG of the light-homogenizing film 200 and depend much more strongly on the dimension D1 between the LED 30 and the QD material 62.

The QD LED module 10 that uses the first example QD material 62 has an average brightness that is greater by between 2× and 3× over QD LED modules associated with typical commercial displays (600≤nits ≤1000).

### Example 2

In a second example, the QD material 62 has a color point (x,y)=(0.41, 0.54), which is in the yellow-green portion of the CIE 1931 color space. This color point has a color point shift (Δx, Δy) measured relative to the measured CIE color point (0.28, 0.20) of Δx=0.13 and Δy=0.34.

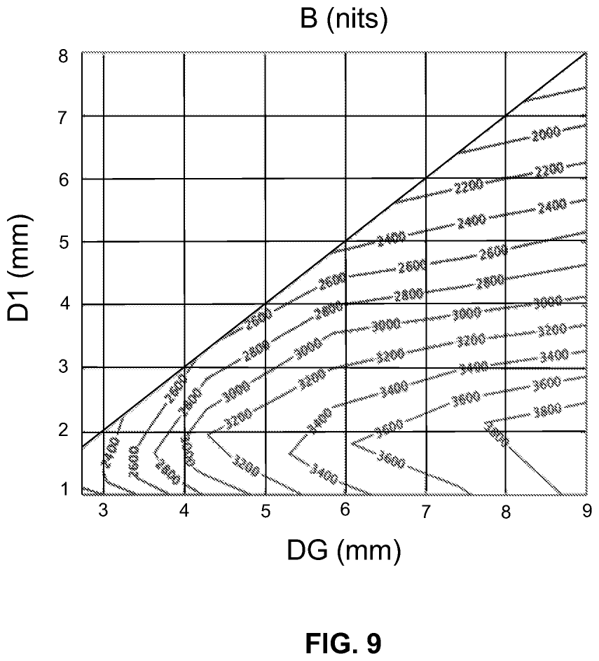

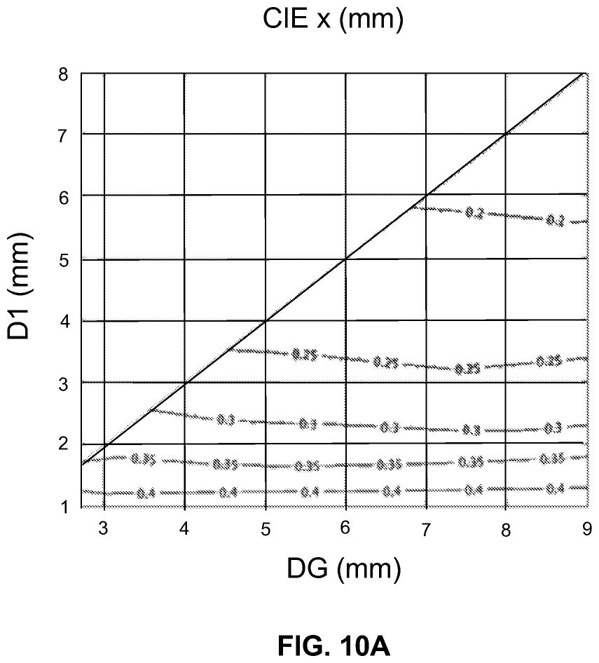

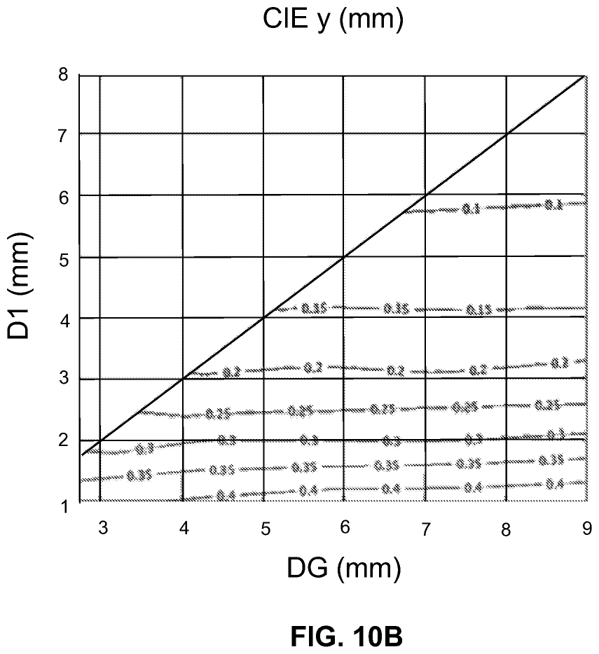

FIG. 9 is similar to FIG. 7 and shows the predicted average brightness B (nits) for the QD LED module 10 as a function of the module dimensions D1 (mm) and DG (mm) for the second example QD material. The QD LED module that employs the second QD material has a brightness that is greater than conventional QD LED modules that employ standard QD material through which blue light is transmitted. FIGS. 10A and 10B are the same as FIGS. 8A and 8B but are for the QD LED module that uses the second example QD material. The predicted average CIE x and y color coordinates of FIGS. 10A and 10B fall very close to a “perfect” white light (x,y) color-point.

### Relative Color Point Shift and Advantages

In an example, the color point shift (Δx, Δy) of the color-shifted QD material 62 disclosed herein can be measured relative to the FOS color point (0.28, 0.24), in which case the color shift for the x coordinate is Δx>0.15 and for they coordinate is Δy>0.15. Also in an example, the (x,y) color point for the QD material 62 is in the range x>0.4 and y>0.45. In another example, the color point for the QD material is in the range x>0.35 and y>0.375.

A color point shift (Δx, Δy) in the CIE color point (x,y) of the QD material 62 relative to standard QD material (e.g., having a CIE color point of (x,y)=(0.28, 0.2) or (0.28, 0.24) enables a lower flux of blue light 36B on the QD material 62 of the QD structure 60 thereby enabling longer operation of the QD LED module 10. As noted above, it also can enable increased brightness as compared to conventional QD LED modules, e.g., by about 15%.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

1. A quantum-dot light-emitting-diode (QD LED) module, comprising:
a support assembly having an interior;
a circuit board;
an LED operably supported by the circuit board, the LED having a surface that emits blue light; and
a QD structure supported within the interior of the support assembly and axially spaced apart from the LED surface by a distance D1, the QD structure having an active area that comprises at least one first region of QD material and at least one second region that has no QD material, wherein a first portion of the blue light from the LED passes through the at least one first region and is converted by the QD material to red and green light, and wherein a second portion of the blue light passes through the at least one second region.

2. The QD LED module according to claim 1, further comprising a spacer layer disposed between the LED and the QD structure so that there is no air space between the LED and the QD structure.

3. The QD LED module according to claim 1, further comprising a light-homogenizing medium supported by the support assembly and that resides downstream of the QD structure.

4. The QD LED module according to claim 1, further comprising a hermetic seal disposed downstream of the QD structure.

5. The QD LED module according to claim 1, and further comprising a lens element disposed downstream of the QD structure and supported by the support assembly.

6. The QD LED module according to claim 1, wherein the QD material of the at least one first region has an (x,y) CIE color point of x>0.35 and y>0.375.

7. (canceled)

8. The QD LED module according to claim 1, further comprising a scattering layer disposed downstream of the QD structure.

9. (canceled)

10. The QD LED module according to claim 1, wherein the distance D1 is in the range from 0.5 mm to 7 mm.

11. A quantum-dot light-emitting-diode (QD LED) module, comprising:
a support assembly having an interior;
a circuit board;
an LED operably supported by the circuit board, the LED having a surface that emits blue light;
a QD structure supported within the interior of the support assembly and axially spaced apart from the LED surface by a distance D1, the QD structure having an active area that includes at least one first region of QD material and at least one second region that has no QD material, wherein a first portion of the blue light from the LED passes through the at least one first region and is converted to red and green light by the QD material, and wherein a second portion of the blue light passes through the at least one second region; and
at least one spacer layer disposed between the LED and the QD structure so that there is no air space between the LED and the QD structure.

12. The QD LED module according to claim 11, wherein the at least one spacer layer comprises silicone, further wherein at least a portion of the silicone includes scattering particles that scatter the blue light.

13. (canceled)

14. The QD LED module according to claim 12, wherein heat is generated within the interior of the support assembly by the LED, and wherein at least a portion the support assembly is made of a metal that conducts the heat to the circuit board.

15. The QD LED module according to claim 12, wherein the QD material of the at least one first region has an (x,y) CIE color point of x>0.35 and y>0.375.

16. (canceled)

17. (canceled)

18. (canceled)

19. (canceled)

20. (canceled)

21. (canceled)

22. A method of forming white light using a quantum dot (QD) material supported on a QD structure, comprising:
generating blue light from a light-emitting diode (LED);
passing a first portion of the blue light through the QD material of the QD structure to form green and red light;
passing a second portion of the blue light through the QD structure but not through any of the QD material; and
combining the green and red light and the second portion of the blue light to form the white light.

23. The method according to claim 22, wherein the QD material has an (x,y) CIE color point of x>0.35 and y>0.375.

24. The method according to claim 23, wherein x>0.40 and y>0.45.

25. The method according to claim 22, wherein the QD material is supported by the QD structure in separate regions.

26. The method according to claim 22, further comprising scattering at least the first portion of the blue light prior the first portion of the blue light being incident upon the QD material.

27. The method according to claim 22, wherein said combining comprises passing the second portion of the blue light and the red light and the green light through a light-homogenizing medium.

28. The method according to claim 22, further comprising passing the first and second portions of the blue light through at least one spacer layer disposed between the LED and the QD structure, wherein there is no air space between the LED and the QD structure.

29. The method according to claim 28, wherein the at least one spacer layer includes a scattering layer that scatters the blue light.

30. (canceled)

31. (canceled)
